(19) United States
(12) Patent Application Publication
(10) Pub. No.: US 2023/0290611 A1
(43) Pub. Date: Sep. 14, 2023

(54) DISTRIBUTED PLASMA SOURCE ARRAY

(71) Applicant: LAM RESEARCH CORPORATION, Fremont, CA (US)

(72) Inventors: Neil M. P. BENJAMIN, Palo Alto, CA (US); Roger PATRICK, Mountain View, CA (US)

(21) Appl. No.: 17/927,328

(22) PCT Filed: May 10, 2021
(86) PCT No.: PCT/US2021/031490

§ 371 Date: Nov. 22, 2022

Related U.S. Application Data
(60) Provisional application No. 63/030,644, filed on May 27, 2020.

(51) Int. Cl. H01J 37/32

(52) U.S. Cl. CPC H01J 37/32119; H01J 37/3211; H01J 37/32174

(57) ABSTRACT

A substrate processing system includes a processing chamber including a window. A substrate support is arranged inside the processing chamber to support a substrate during plasma processing. A first array including E inductive coils arranged adjacent to and outside of the processing chamber, where E is an integer greater than three. A second array includes D RF direct drive circuits configured to output RF power to the first array, where D is an integer greater than three, and to generate plasma inside of the processing chamber.

### CROSS-REFERENCE TO RELATED APPLICATIONS

The present disclosure is a PCT International Application of U.S. Provisional Pat. Application No. 63/030,644 filed on May 27, 2020. The entire disclosure of the application referenced above is incorporated herein by reference.

### FIELD

The present disclosure relates to substrate processing systems, and more particularly to a distributed plasma source array for substrate processing systems.

### BACKGROUND

The background description generally presents the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning and/or other processes. Process gas mixtures, supplied to the processing chamber, treat an exposed surface of the substrate. Plasma may be ignited in the processing chamber to enhance chemical reactions within the processing chamber.

For example, substrate processing systems may be used to etch an exposed surface of substrates such as semiconductor wafers. Dry etching may be performed using plasma generated by inductively coupled plasma (ICP). One or more inductive coils arranged outside of the processing chamber (adjacent to a dielectric window) generate a magnetic field. The delivered RF energy ignites the process gases flowing inside the processing chamber to create plasma. In some applications, RF bias power may also be supplied to an electrode in the substrate support. The inductive coils generate a magnetic field that varies at different locations within the processing chamber, which leads to process non-uniformity.

When performing other treatments using capacitively coupled plasma (CCP), an upper electrode is arranged inside of the processing chamber and RF power is supplied to the upper electrode. Another electrode is arranged in the substrate support. Process gases such as precursor and carrier gas are supplied to the processing chamber. An electric field is generated across the upper and lower electrodes to generate plasma. In some cases, a conductive showerhead distributes process gases and acts as the upper electrode. In other cases, the electrode does not act as a showerhead and the process gases are supplied to the processing chamber in another manner. The electrodes generate an electric field that varies at different locations within the processing chamber, which leads to process non-uniformity.

### SUMMARY

A substrate processing system includes a processing chamber including a window. A substrate support is arranged inside the processing chamber to support a substrate during plasma processing. A first array including E inductive coils arranged adjacent to and outside of the processing chamber, where E is an integer greater than three. A second array includes D RF direct drive circuits configured to output RF power to the first array, where D is an integer greater than three, and to generate plasma inside of the processing chamber.

In other features, a distance between a top surface of the substrate support and a bottom surface of the window is in a range from 0.4″ to 6″. A distance between a top surface of the substrate support and a bottom surface of the window is in a range from 1″ to 3″. The E inductive coils have a circular outer shape. The E inductive coils have a hexagonal outer shape. The E inductive coils are arranged in a rectangular array. The E inductive coils are arranged in a hexagonal array. The E inductive coils have an outer diameter in a range from 1″ to 6″. The E inductive coils have an outer diameter in a range from 3″ to 6″.

In other features, the first array further includes F inductive coils have at least one of a size and a shape that is different than the E inductive coils, where F is an integer greater than two. Each of the E inductive coils includes a first inductive coil arranged inside of a second inductive coil. Each of the E inductive coils includes a first inductive coil inter-wound with a second inductive coil. The window is made of a dielectric material. The window includes a frame portion and defines E cavities. The E inductive coils in the first array are arranged in the E cavities of the frame portion.

In other feature, E windows are arranged in a substrate-facing opening of the E cavities. A dielectric window is arranged on a substrate-facing side of the frame portion.

In other features, each of the D RF direct drive circuits includes a clock generator to generate a clock signal at a first frequency. A gate driver receives the clock signal. A bridge circuit includes a first switch with a control terminal connected to the gate driver, a first terminal and a second terminal; a second switch with a control terminal connected to the gate driver, a first terminal connected to the second terminal of the first switch and an output node, and a second terminal. A first DC supply supplies a first voltage potential to the first terminal of the first switch. A second DC supply supplies a second voltage potential to the second terminal of the second switch.

In other features, the first voltage potential and the second voltage potential have opposite polarity and are approximately equal in magnitude. The second voltage potential is ground.

In other features, a current sensor senses current at the output node and generates a current signal. A voltage sensor senses a voltage at the output node and generates a voltage signal. A controller includes a phase offset calculator to calculate a phase offset between the voltage signal and the current signal. A clock adjuster adjusts the first frequency based on the phase offset.

In other features, the clock adjuster increases the first frequency when the current leads the voltage and decreases the first frequency when the voltage leads the current. Each of the D RF direct drive circuits includes a first inductor including a first end and a second end; a second inductor including a first end in communications with the first end of the first inductor and a second end; a first switch including a first terminal, a second terminal and a control terminal; a second switch including a first terminal, a second terminal and a control terminal; a first capacitor including a first end and a second end. The first end of the first capacitor is in communication with the second end of the first inductor and the first terminal of the first switch. A second capacitor includes a first end and a second end. The second end of the second capacitor is in communication with the second end of the second inductor and the second terminal of the second switch. The second terminal of the first switch communicates with the first terminal of the second switch, the second end of the first capacitor and the first end of the second capacitor.

In other features, a third capacitor including a first end in communication with the first end of the first capacitor and a second end in communication with a first end of at least one of the E inductive coils. A fourth capacitor includes a first end in communication with the second end of the second capacitor and a second end in communication with a second end of the at least one of the E inductive coils.

In other features, a voltage source has one end connected to the first end of the first inductor and the first end of the second inductor and a second end connected to the second terminal of the first switch and the first terminal of the second switch. The voltage source supplies DC voltage.

In other features, an inductive coil surrounds the first array. A controller is configured to control the second array. S sensors are configured to sense S operational parameters corresponding to the second array, respectively, where S is an integer greater than three.

In other features, the controller is configured to alter operation of the D RF direct drive circuits based on the S operational parameters sensed by the S sensors, respectively. The processing chamber includes side walls and further comprising one or more inductive coils each including one or more turns wound around an upper portion of the side walls. The first array is arranged in a first plane above the window and the one or more inductive coils are arranged below the first plane.

In other features, a third array includes F inductive coils that are embedded within the window, where F is an integer greater than three. The E inductive coils deliver RF energy to the F inductive coils. The E inductive coils of the first array are larger than the F inductive coils of the third array. F is greater than E.

In other features, a third array includes G electrodes embedded in the substrate support, where G is an integer greater than three. A fourth array includes H RF direct drive circuits configured to output RF power to the first array, where H is an integer greater than three.

In other features, a third array including G electrodes embedded in the substrate support, where G is an integer greater than three. A fourth array includes H RF direct drive circuits configured to output RF power to the first array, where H is an integer greater than three.

A substrate processing system includes a processing chamber including an outer surface that is non-planar. A substrate support is arranged inside the processing chamber to support a substrate during plasma processing. A first array includes E inductive coils arranged adjacent to and outside of the outer surface of the processing chamber, where E is an integer greater than three. A second array includes D RF direct drive circuits configured to output RF power to the first array, where D is an integer greater than three, and to generate plasma inside of the processing chamber.

In other features, the outer surface of the processing chamber is dome-shaped. The E inductive coils have a non-planar side cross-sectional shape conforming to the outer surface of the processing chamber.

In other features, each of the D RF direct drive circuits include a clock generator to generate a clock signal at a first frequency and a gate driver to receive the clock signal. A bridge circuit includes a first switch with a control terminal connected to the gate driver, a first terminal and a second terminal. A second switch includes a control terminal connected to the gate driver, a first terminal connected to the second terminal of the first switch and an output node, and a second terminal. A first DC supply supplies a first voltage potential to the first terminal of the first switch. A second DC supply supplies a second voltage potential to the second terminal of the second switch.

In other features, the first voltage potential and the second voltage potential have opposite polarity and are approximately equal in magnitude. The second voltage potential is ground.

In other features, a current sensor senses current at the output node and to generate a current signal. A voltage sensor senses a voltage at the output node and to generate a voltage signal. A controller includes a phase offset calculator to calculate a phase offset between the voltage signal and the current signal and a clock adjuster to adjust the first frequency based on the phase offset.

In other features, the clock adjuster increases the first frequency when the current leads the voltage and decreases the first frequency when the voltage leads the current. Each of the D RF direct drive circuits include a first inductor including a first end and a second end; a second inductor including a first end in communications with the first end of the first inductor and a second end; a first switch including a first terminal, a second terminal and a control terminal; a second switch including a first terminal, a second terminal and a control terminal; a first capacitor including a first end and a second end. The first end of the first capacitor is in communication with the second end of the first inductor and the first terminal of the first switch. A second capacitor includes a first end and a second end. The second end of the second capacitor is in communication with the second end of the second inductor and the second terminal of the second switch. The second terminal of the first switch communicates with the first terminal of the second switch, the second end of the first capacitor and the first end of the second capacitor.

In other features, a third capacitor includes a first end in communication with the first end of the first capacitor and a second end in communication with a first end of at least one of the E inductive coils. A fourth capacitor includes a first end in communication with the second end of the second capacitor and a second end in communication with a second end of the at least one of the E inductive coils.

In other features, a voltage source has one end connected to the first end of the first inductor and the first end of the second inductor and a second end connected to the second terminal of the first switch and the first terminal of the second switch. The voltage source supplies DC voltage.

In other features, an inductive coil surrounding the first array. A controller is configured to control the second array. D sensors are configured to sense D operational parameters corresponding to the second array, respectively, where D is an integer greater than three. The controller is configured to alter operation of the D RF direct drive circuits based on the D operational parameters sensed by the D sensors, respectively.

A substrate processing system includes a processing chamber; a substrate support arranged in the processing chamber; a first array including E electrodes arranged adjacent to and inside of the processing chamber above the substrate support, where E is an integer greater than three; and a second array including D RF direct drive circuits configured to output RF power to the first array, where D is an integer greater than three.

In other features, the E electrodes have a circular outer shape. The E electrodes have a hexagonal outer shape. The E electrodes are arranged in a rectangular array. The E electrodes are arranged in a hexagonal array. The E electrodes have an outer diameter in a range from 1″ to 6″. The first array further includes F electrodes having at least one of a size and a shape that is different than the E electrodes.

In other features, each of the D RF direct drive circuits includes a clock generator to generate a clock signal at a first frequency and a gate driver to receive the clock signal. A bridge circuit includes a first switch with a control terminal connected to the gate driver, a first terminal and a second terminal. A second switch includes a control terminal connected to the gate driver, a first terminal connected to the second terminal of the first switch and an output node, and a second terminal. A first DC supply supplies a first voltage potential to the first terminal of the first switch. A second DC supply supplies a second voltage potential to the second terminal of the second switch.

In other features, the first voltage potential and the second voltage potential have opposite polarity and are approximately equal in magnitude. The second voltage potential is ground. A current sensor senses current at the output node and generates a current signal. A voltage sensor senses a voltage at the output node and to generate a voltage signal. A controller includes a phase offset calculator to calculate a phase offset between the voltage signal and the current signal and a clock adjuster to adjust the first frequency based on the phase offset.

In other features, the clock adjuster increases the first frequency when the current leads the voltage and decreases the first frequency when the voltage leads the current. Each of the D RF direct drive circuits includes a first inductor including a first end and a second end; a second inductor including a first end in communications with the first end of the first inductor and a second end; a first switch including a first terminal, a second terminal and a control terminal; a second switch including a first terminal, a second terminal and a control terminal; a first capacitor including a first end and a second end. The first end of the first capacitor is in communication with the second end of the first inductor and the first terminal of the first switch. A second capacitor includes a first end and a second end. The second end of the second capacitor is in communication with the second end of the second inductor and the second terminal of the second switch. The second terminal of the first switch communicates with the first terminal of the second switch, the second end of the first capacitor and the first end of the second capacitor.

In other features, a third capacitor includes a first end in communication with the first end of the first capacitor and a second end in communication with a first end of at least one of the E electrodes. A fourth capacitor includes a first end in communication with the second end of the second capacitor and a second end in communication with a second end of the at least one of the E electrodes.

In other features, a voltage source has one end connected to the first end of the first inductor and the first end of the second inductor and a second end connected to the second terminal of the first switch and the first terminal of the second switch. The voltage source supplies DC voltage.

In other features, a controller is configured to control the second array. D sensors configured to sense D operational parameters corresponding to the second array, respectively. The controller is configured to alter operation of the D RF direct drive circuits based on the D operational parameters sensed by the D sensors, respectively.

A substrate processing system includes a processing chamber and a substrate support arranged inside the processing chamber to support a substrate during plasma processing. An upper electrode is arranged above the substrate support. A first array includes E electrodes arranged in the substrate support, where E is an integer greater than three. A second array includes D RF direct drive circuits configured to output RF power to the first array, where D is an integer greater than three.

In other features, the substrate support includes a baseplate and a layer arranged above the baseplate and configured to support a substrate. The first array is embedded in the layer. The layer further includes a plurality of electrostatic electrodes. The layer further includes a plurality of heaters. The upper electrode is connected to a reference potential.

In other features, the substrate processing system includes an RF source and a matching network. The RF source provides RF power to the upper electrode via the matching network. The upper electrode includes a showerhead. The upper electrode includes a third array including P electrodes, where P is an integer greater than three. A fourth array includes Q RF direct drive circuits configured to supply RF power to the third array including P electrodes, where Q is an integer greater than three.

A substrate processing system includes a processing chamber including a dielectric window assembly. A substrate support is arranged inside the processing chamber to support a substrate. E inductive coils are embedded in the dielectric window assembly, where E is an integer greater than three. D RF direct drive circuits are configured to output RF power to the E inductive coils, where D is an integer greater than three, and to generate plasma inside of the processing chamber.

In other features, the dielectric window assembly includes a first dielectric window having a first thickness and arranged on a vacuum side of the processing chamber. A second dielectric window has a second thickness and arranged on an atmospheric side of the processing chamber. The E inductive coils are arranged between the first dielectric window and the second dielectric window. The first thickness is less than the second thickness. The first thickness is in a range from 1/16″ to ¾″ and the second thickness is in a range from ½″ to 3″. Conductors pass through the second dielectric window and directly connect the D RF direct drive circuits to the E inductive coils.

In other features, G inductive coils are arranged on the atmospheric side, where G is an integer greater than zero. The G inductive coils are directly connected to the D RF direct drive circuits, The G inductive coils indirectly supply the RF power from the D RF direct drive circuits though the second dielectric window to the E inductive coils.

Each of the D RF direct drive circuits include a clock generator to generate a clock signal at a first frequency and a gate driver to receive the clock signal. A bridge circuit includes a first switch with a control terminal connected to the gate driver, a first terminal and a second terminal. A second switch includes a control terminal connected to the gate driver, a first terminal connected to the second terminal of the first switch and an output node, and a second terminal. A first DC supply supplies a first voltage potential to the first terminal of the first switch. A second DC supply supplies a second voltage potential to the second terminal of the second switch.

In other features, the first voltage potential and the second voltage potential have opposite polarity and are approximately equal in magnitude. The second voltage potential is ground.

In other features, a current sensor to sense current at the output node and to generate a current signal and a voltage sensor to sense a voltage at the output node and to generate a voltage signal. A controller includes a phase offset calculator to calculate a phase offset between the voltage signal and the current signal and a clock adjuster to adjust the first frequency based on the phase offset.

In other features, the clock adjuster increases the first frequency when the current leads the voltage and decreases the first frequency when the voltage leads the current. Each of the D RF direct drive circuits include a first inductor including a first end and a second end; a second inductor including a first end in communications with the first end of the first inductor and a second end; a first switch including a first terminal, a second terminal and a control terminal; a second switch including a first terminal, a second terminal and a control terminal; a first capacitor including a first end and a second end. The first end of the first capacitor is in communication with the second end of the first inductor and the first terminal of the first switch. A second capacitor includes a first end and a second end. The second end of the second capacitor is in communication with the second end of the second inductor and the second terminal of the second switch. The second terminal of the first switch communicates with the first terminal of the second switch, the second end of the first capacitor and the first end of the second capacitor.

In other features, a third capacitor includes a first end in communication with the first end of the first capacitor and a second end in communication with a first end of at least one of the E inductive coils. A fourth capacitor includes a first end in communication with the second end of the second capacitor and a second end in communication with a second end of the at least one of the E inductive coils. A voltage source has one end connected to the first end of the first inductor and the first end of the second inductor and a second end connected to the second terminal of the first switch and the first terminal of the second switch.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a capacitively coupled plasma (CCP) substrate processing system according to the present disclosure;

FIGS. 1B to 1D illustrate examples of arrays of RF electrodes according to the present disclosure;

FIG. 2A is a functional block diagram of an example of an inductively coupled plasma (ICP) substrate processing system according to the present disclosure;

FIGS. 2B to 2I illustrate examples of coils that can be used in the array of RF coils according to the present disclosure;

FIGS. 3A and 3F illustrate examples of arrays of RF coils according to the present disclosure;

FIG. 4A illustrates an example layout of RF coils arranged around a nonplanar processing chamber according to the present disclosure;

FIGS. 4B and 4C illustrate an example of a non-planar inductive coil according to the present disclosure;

FIG. 5A illustrates an example of an array of RF coils arranged in recesses in a window according to the present disclosure;

FIGS. 5B to 5D are cross-sectional views of examples of the window and array of RF coils according to the present disclosure;

FIGS. 6A and 6B are plan views illustrating an array of RF coils surrounded by one or more outer coils according to the present disclosure;

FIG. 7 is a functional block diagram of an example of a control system for an array of RF direct drive circuits and an array of RF coils or electrodes according to the present disclosure;

FIG. 8 illustrates an example of a direct drive circuit used in the substrate processing system according to the present disclosure;

FIG. 9 illustrates another example of a direct drive circuit used in the substrate processing system according to the present disclosure;

FIG. 10A is a perspective view of an example of a coil system including an array of coils arranged adjacent to a window and other coils wound around the processing chamber;

FIG. 10B is a side cross-sectional view of the coil system of FIG. 10A;

FIG. 10C is a side cross-sectional view of another example of the coil system of FIG. 10A;

FIG. 11A is a plan view illustrating an example of a coil system including a first array of coils embedded in a window according to the present disclosure;

FIG. 11B is a side cross-sectional view of the coil system of FIG. 11A;

FIG. 11C is a plan view illustrating a coil system including a first array of coils arranged adjacent to a window that deliver RF power to a second array of coils embedded in the window according to the present disclosure;

FIG. 11D is a side cross-sectional view of the coil system of FIG. 11C;

FIG. 12A is a functional block diagram of an example of an array of electrodes arranged in a substrate support according to the present disclosure;

FIG. 12B is a functional block diagram of another example of an array of electrodes driven by RF direct drive circuits and embedded in a substrate support according to the present disclosure;

FIG. 12C is a plan view of an example of a substrate support with embedded electrodes according to the present disclosure;

FIG. 12D is a functional block diagram of another example of a first array of electrodes embedded in a substrate support and a second array of electrodes arranged above the substrate support according to the present disclosure;

FIG. 13A is a functional block diagram of a processing chamber including an array of coils arranged adjacent to a window and driven by RF direct drive circuits and a substrate support including an array of RF electrodes driven by RF direct drive circuits according to the present disclosure; and

FIG. 13B is a functional block diagram of a processing chamber including coils arranged adjacent to a window and driven by an RF source and matching network and a substrate support including an array of RF electrodes driven by RF direct drive circuits according to the present disclosure.

In the drawings, reference numbers may be reused to identify similar and/or identical elements.

### DETAILED DESCRIPTION

Plasma processing systems typically include an RF generator that supplies RF power to a load such as an RF electrode for capacitively coupled plasma applications (CCP) and/or one or more RF inductive coils for inductively coupled plasma (ICP) applications. The RF generator typically includes an RF source, a matching network and a connecting conductor such as a coaxial cable. Due to the high power and high frequencies that are used, the RF generators typically use discrete inductive and capacitive components that are relatively large and expensive. As a result, it is difficult to package the RF generators near loads such as electrodes and/or inductive coils, particularly when multiple loads may need to be driven.

The matching network matches an output impedance of the RF source to an impedance of the load. The RF source may provide RF power in a range of 1 to 10 kW (or 1 to 5 kW) at frequencies in a range from 20 KHz to 3 GHz, although other power output levels and/or frequencies can be used.

Given the large size and cost of the RF generators, generally only one or a few are used in commercial substrate processing systems. In some examples, improved control of process uniformity can sometimes be accomplished by dividing system input into zones that are individually monitored and controller. This approach would allow the individual RF generators (and corresponding inductive coils and/or electrodes) to be individually driven to allow fine-tuning of the plasma in the processing chamber. However, the increased cost and packaging size of traditional RF generators, matching networks and transmission lines has prevented this approach from being used commercially.

While larger gaps can be used between a top surface of the substrate and a bottom surface of the electrode in CCP applications (or a bottom surface of the dielectric window (and the inductive coils) in ICP applications), control of the plasma characteristics is particularly important in difficult applications with relatively small gaps (e.g. greater than or equal to 0.4″ and less than or equal to 6″, 5″, 4″, 3″, or 2″).

Systems and methods according to the present disclosure use an array of RF direct drive circuits to supply power to an array of inductive coils (e.g. in ICP applications) or an array of electrodes (e.g. in CCP applications). Due to the design of the RF direct drive circuits described herein, the overall size and cost of the RF generators can be significantly reduced and they can be arranged near the loads. In some examples, the RF direct drive circuits include two or more switches that are alternately driven at about a 50% duty cycle. In some examples, the RF direct drive circuits described herein generally have low output impedance (typically less than 10 ohms, e.g. around 1 ohm). The RF direct drive circuits described herein do not generally require matching networks with discrete components or high impedance coaxial transmission lines. The RF direct drive circuits can be packaged using integrated circuits and printed circuit boards, which reduces the overall cost and packaging size. As a result, improved control of the plasma can be achieved.

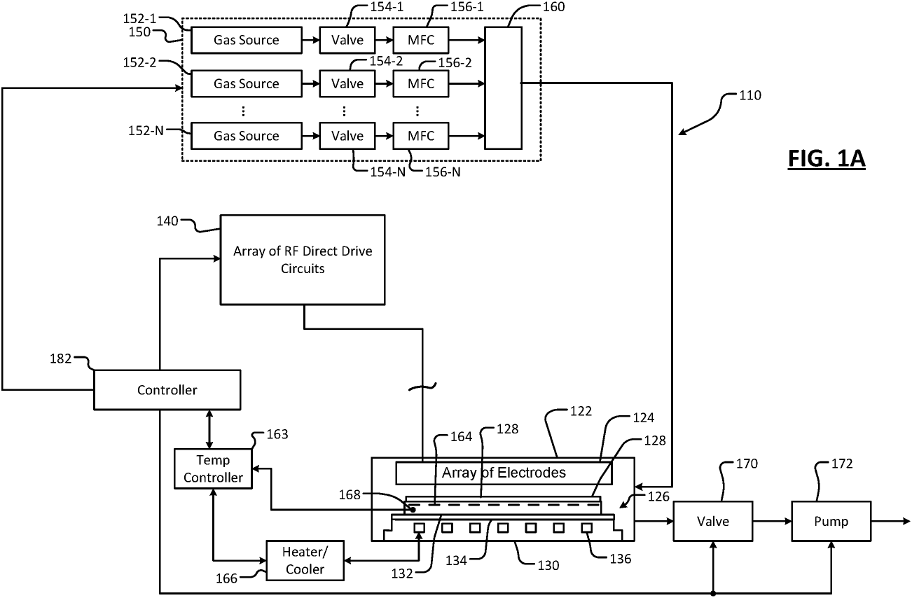

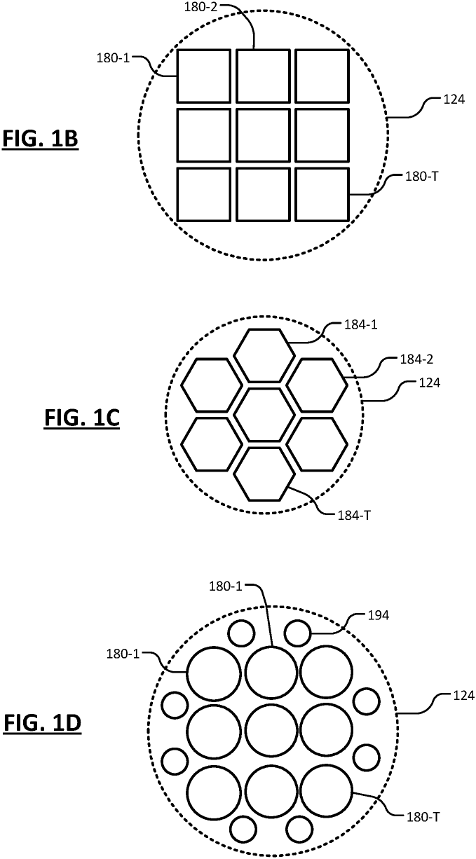

Referring now to FIG. 1A, an example of a plasma processing chamber using capacitively coupled plasma to process substrates is shown. While a specific type of plasma processing chambers is shown for illustration purposes, other types of plasma processing chambers can be used. In FIG. 1A, a substrate processing system 110 may be used to perform etching, deposition or other substrate treatment using capacitively coupled plasma (CCP).

The substrate processing system 110 includes a processing chamber 122 that encloses other components of the substrate processing system 110 and contains the RF plasma. The substrate processing system 110 includes an array of RF electrodes 124 and a substrate support 126 such as an electrostatic chuck (ESC). During operation, a substrate 128 is arranged on the substrate support 126. The array of RF electrodes 124 includes a plurality of RF electrodes.

The substrate support 126 includes a baseplate 130 that acts as a lower electrode. An upper layer 132 is arranged above the baseplate 130 and is configured to support a substrate during processing. In some examples, the upper layer 132 further includes heaters that may be arranged in two or more zones, electrostatic electrodes to clamp the substrate and/or backside gas channels arranged on an upper surface of the upper layer 132. A bonding and/or a thermal resistance layer 134 may be arranged between the upper layer 132 and the baseplate 130. The baseplate 130 may include one or more channels 136 for flowing coolant through the baseplate 130.

An array of RF direct drive generators 140 generates and outputs a plurality of RF voltages to the array of RF electrodes 124. The baseplate 130 may be DC grounded, AC grounded or floating. In some examples, the array of RF electrodes 124 includes A electrodes and the array of RF direct drive generators 140 includes B RF direct drive generators, where A and B are integers greater than one. In some examples, B is less than or equal to A and B is greater than one. In some examples, A is less than or equal to B and A is greater than one. In some examples, A=B and there is a one to one correspondence between the RF direct drive circuits and the RF electrodes. In other examples, B < A and a single direct drive circuit drives two or more electrodes. For example, the electrodes can be arranged in Z zones, where Z is an integer greater than two) and each RF direct drive circuit drives some or all of the electrodes in a given zone. Each of the Z zones includes one or more electrodes.

A gas delivery system 150 delivers gas mixtures to the processing chamber including process gas, carrier gas, etching gas, precursor gases, inert gases, etc. and mixtures thereof. The gas delivery system 150 includes one or more gas sources 152-1, 152-2, ..., and 152-N (collectively gas sources 152), where N is an integer greater than zero. The gas sources 152 are connected by valves 154-1, 154-2, ..., and 154-N (collectively valves 154) and MFCs 156-1, 156-2, ..., and 156-N (collectively MFCs 156) to a manifold 160. Secondary valves may be used between the MFCs 156 and the manifold 160. While a single gas delivery system 150 is shown, two or more gas delivery systems can be used.

A temperature controller 163 may be connected to a plurality of thermal control elements (TCEs) 164 arranged in the upper layer 132. The temperature controller 163 may be used to control the plurality of TCEs 164 to control a temperature of the substrate support 126 and the substrate 128. The temperature controller 163 may communicate with a coolant assembly 166 to control coolant flow through the channels 136. For example, the coolant assembly 166 may include a coolant pump, a reservoir and/or one or more temperature sensors (see e.g. 168). The temperature controller 163 operates the coolant assembly 166 to selectively flow the coolant through the channels 136 to cool the substrate support 126.

A valve 170 and pump 172 may be used to evacuate reactants from the processing chamber 122. A system controller 182 may be used to control components of the substrate processing system 110 as will be described further below.

Referring now to FIGS. 1B and 1C, examples of the array of RF electrodes 124 are shown. The RF electrodes in the array of RF electrodes 124 can have any suitable shape and can be arranged in arrays having different configurations (such as Cartesian, hexagonal, circular, rectangular, etc.). In FIG. 1B, the array of RF electrodes 124 is arranged in a rectangular array. The array of RF electrodes 124 includes electrodes 180-1, 180-2, ..., and 180-T, where T is an integer greater than or equal to two (collectively RF electrodes 180). In some examples, the electrodes are rectangular-shaped, elliptical-shaped, or polygonal-shaped, although other regular and/or irregular shapes can be used. While the array of RF electrodes 124 includes 9 electrodes in FIG. 1B, the array can include fewer electrodes (such as 4) or additional electrodes (such as 16, 25, etc.).

In FIG. 1C, the array of RF electrodes 124 are arranged in a hexagonal array. The array of RF electrodes 124 includes electrodes 184-1, 184-2, ..., and 184-T, where T is an integer, (collectively electrodes 184). In some examples, the electrodes 184 are hexagonal-shaped. While the array of RF electrodes 124 includes 7 electrodes in FIG. 1B, the array can include fewer (such as 3) or additional electrodes (such as 17, etc.).

Referring now to FIG. 1D, the array of RF electrodes 124 can further include one or more electrodes 194 having a different size, shape, material and/or thickness. In other examples, a gap distance between a bottom surface of the electrode and a top surface of the substrate or substrate support is varied. For example, the electrodes 194 in FIG. 1D have a smaller outer diameter as compared to RF electrodes 180. The electrodes 194 allow further tuning of the plasma. The electrodes 180, 194 may be individually driven by RF direct drive circuits and/or grouped and driven by RF direct drive circuits.

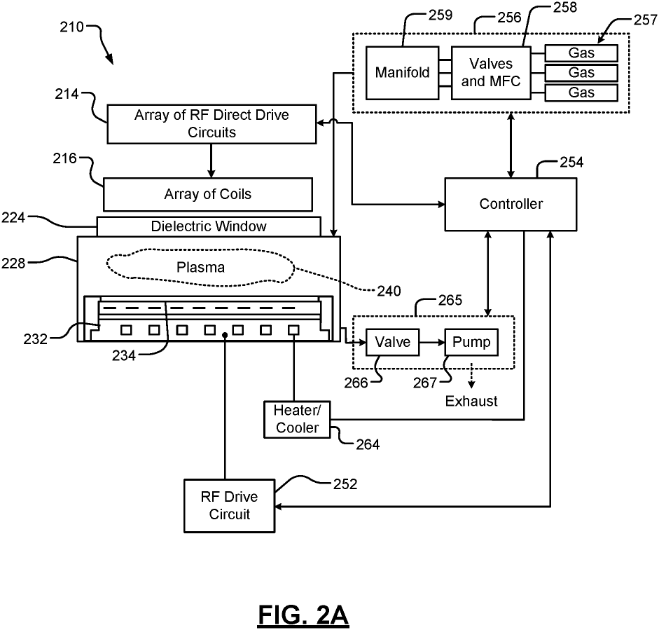

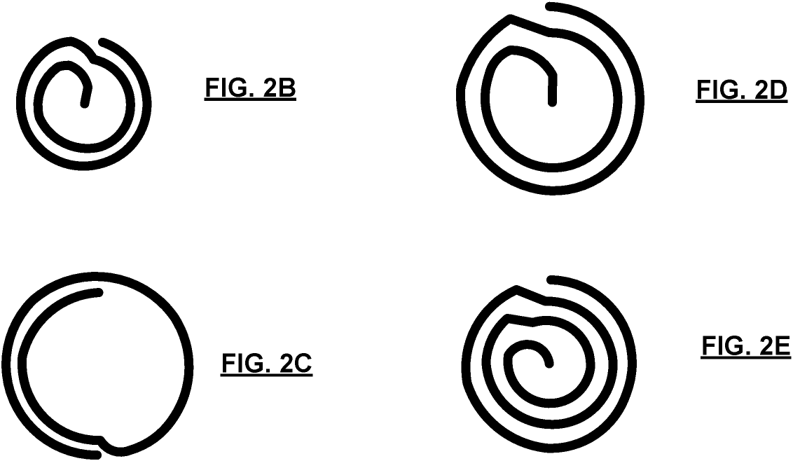

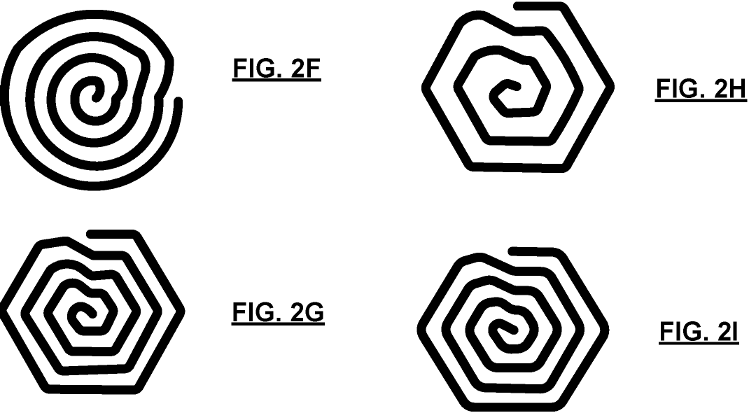

Referring now to FIG. 2A, another example of a substrate processing system 210 according to the present disclosure is shown. The substrate processing system 210 uses inductively coupled plasma to perform etching. The substrate processing system 210 includes an array of RF direct drive circuits 214 and an array of inductive coils 216.

In some examples, a window 224 is arranged along one side of a processing chamber 228. In some examples, the window 224 may be made of dielectric material that is substantially transparent to the magnetic fields that are produced by the inductive coils at the frequency of interest. The array of inductive coils 216 are arranged adjacent to the window 224. The processing chamber 228 further comprises a substrate support (or pedestal) 232. The substrate support 232 may include an electrostatic chuck (ESC), or a mechanical chuck or other type of chuck. Process gas is supplied to the processing chamber 228 and plasma 240 is generated inside of the processing chamber 228. The plasma 240 etches an exposed surface of the substrate 234.

A gas delivery system 256 supplies a process gas mixture to the processing chamber 228. The gas delivery system 256 may include process and inert gas sources 257, a gas metering system 258 such as valves and mass flow controllers, and a manifold 259. A heater/cooler 264 may be used to heat/cool the substrate support 232 to a predetermined temperature. An exhaust system 265 includes a valve 266 and pump 267 to remove reactants from the processing chamber 228 by purging or evacuation. A controller 254 may be used to control the etching process. The controller 254 monitors system parameters and controls delivery of the gas mixture, striking, maintaining and extinguishing the plasma, removal of reactants, supply of cooling gas, and so on.

Referring now to FIGS. 2B to 21, various examples of inductive coils that can be used in the array of coils are shown. In some examples, the inductive coils in the array have an outer diameter in a range from 1″ to 7″. In other examples, the inductive coils have an outer diameter in a range from 3″ to 6″. In some examples, the inductive coils in the array have a number of turns in a range from 2 to 10. In other examples, the inductive coils in the array have a number of turns in a range from 2 to 5. In some examples, the inductive coils are formed by traces deposited on a PCB. In other examples, the inductive coils include air coil inductors that are attached to a printed circuit board (PCB).

In FIGS. 2B to 2F, the inductive coils have an elliptical/circular outer shape and include a variable number of turns and variable gap distance between turns. In FIG. 2B, the inductive coil has an outer diameter in a range from 3″ to 6″ (e.g. 4″), 2 turns and a gap distance of 0.8″. The inductive coil has a uniformity of 69%.

In FIG. 2C, the inductive coil has an outer diameter in a range from 4.5″ to 6.5″ (e.g. 5.75″), 1.5 turns and a gap distance of 0.5″. The inductive coil has a uniformity of 38%. In FIG. 2D, the inductive coil has an outer diameter in a range from 3″ to 6″ (e.g. 5.75″) and 2 turns. In FIG. 2E, the inductive coil has an outer diameter in a range from 3″ to 6″ (e.g. 5.25″), three turns and a gap distance of 1.75″. The inductive coil has a uniformity of 8.8%. In FIG. 2F, the inductive coil has an outer diameter in a range from 3″ to 6″ (e.g. 5.75″), four turns and a gap distance of 1.0″. The inductive coil has a uniformity of 9.7%.

In FIGS. 2G to 21, the inductive coils have a hexagonal outer shape and include a variable number of turns. In FIG. 2G, the inductive coil has an outer diameter in a range from 3″ to 6″ (e.g. 5.25″), 4 turns and a gap distance of 1.175″. The inductive coil has a uniformity of 7.6%. In FIG. 2H, the inductive coil has an outer diameter in a range from 3″ to 6″ (e.g. 5.25″), 4 turns and a gap distance of 2.5″. The inductive coil has a uniformity of 6.9%. As can be appreciated, uniformity can be affected by chamber pressure, the number of turns, the shape of the coil and/or gap distance.

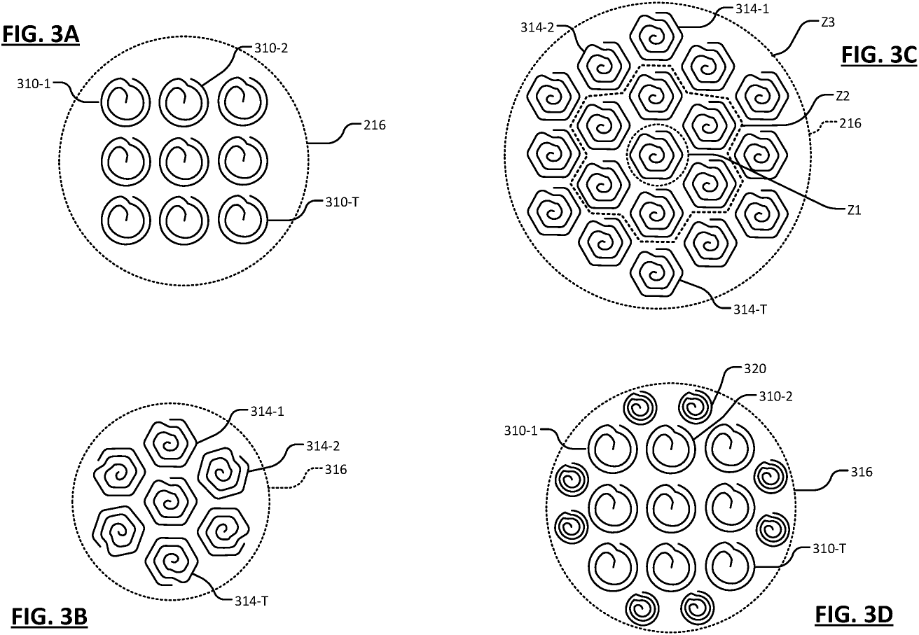

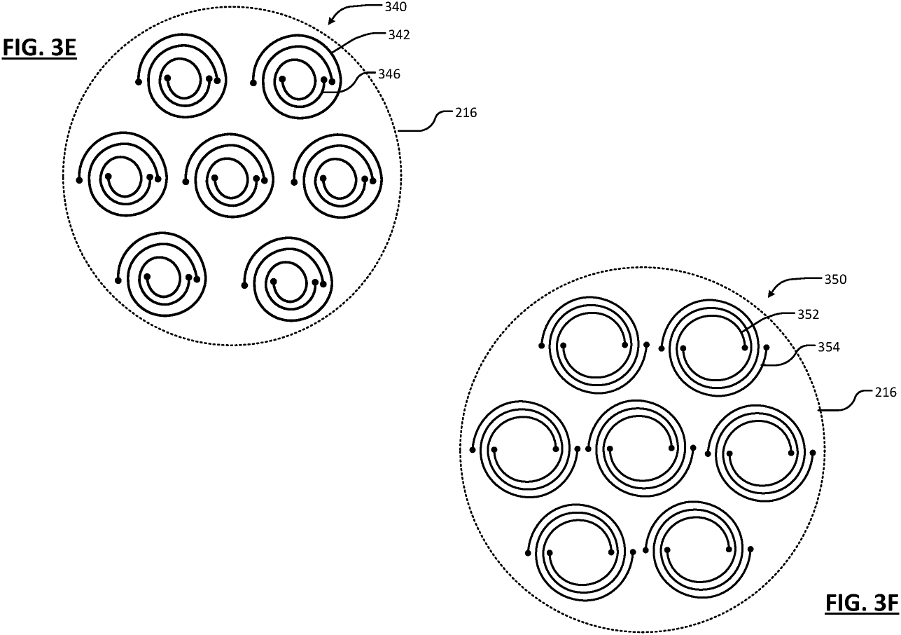

Referring now to FIGS. 3A and 3F, additional examples of the array of inductive coils 216 are shown. The individual coils in the array of inductive coils 216 can have any suitable outer shape and the inductive coils can be arranged in different array patterns. In FIG. 3A, the array of inductive coils 216 is arranged in a rectangular array. The array of inductive coils 216 includes coils 310-1, 310-2, ..., and 310-T, where T is an integer greater than or equal to three (collectively inductive coils 310). In some examples, an outer edge of the inductive coils 310 is rectangular-shaped, elliptical-shaped, and/or polygonal-shaped, although other regular shapes and/or irregular shapes can be used.

In the example in FIG. 3A, the inductive coils have a circular outer shape and are arranged in a rectangular array. While the array of inductive coils 216 includes 9 coils in FIG. 3A, the array can include fewer coils (such as 4) or additional coils (such as 16, 25, 36, etc.). Orientations of the inductive coils 310 can be adjusted relative to positions of the respective coils.

As can be seen in FIG. 3B, the inductive coils 310 can be arranged in a hexagonal array and can have a hexagonal outer shape. In some examples, the inductive coils 310 are clocked or rotated by 360°/C around a periphery of the array of coils (where C is the number of coils along the outer side of the array) (e.g. C=6 in FIG. 3B). The array of inductive coils 216 in FIG. 3B includes inductive coils 314-1, 314-2, ..., and 314-T, where T is an integer, (collectively inductive coils 314). While the array of RF coils 329 includes 7 coils in FIG. 3B, the array can include additional coils (such as 17, etc.) as shown in FIG. 3C.

In FIG. 3C, the inductive coils 314 can be associated with different zones. For example, three zones Z1, Z2 and Z3 are shown, although additional or fewer zones can be used. Each of the zones Z1, Z2, and Z3 is associated with one or more RF direct drive circuits. For example, the zone Z1 includes one inductive coil that is driven by one RF direct drive circuit. In some examples, the zone Z2 includes 6 coils that are driven by 1 to 6 RF direct drive circuits and the zone Z3 includes 12 coils that are driven by 1 to 12 RF direct drive circuits.

Referring now to FIG. 3D, the array of inductive coils 216 can further include one or more inductive coils 320 having a different size, coil thickness, number of turns and/or shape. For example, the inductive coils 320 in FIG. 3D have a smaller outer diameter and an increased number of turns as compared to the inductive coils 310. The inductive coils 320 are arranged in locations that are not large enough to fit another one of the inductive coils 310. The inductive coils 320 allow further tuning of the plasma. The inductive coils 320 may be individually driven by one or more RF direct drive circuits and/or grouped and driven by one or more RF direct drive circuits.

Referring now to FIGS. 3E and 3F, each of the inductive coils in the array of inductive coils 216 can include one or more coils. For example in FIG. 3E, the array of inductive coils 216 includes two or more coils 340 that are nested and that include an outer coil 342 and an inner coil 346. The outer coil 342 and the inner coil 346 can be driven by the same RF direct drive circuit, one or more RF direct drive circuits or different RF direct drive circuits. In some examples, the outer coil 342 and the inner coil 346 are driven with current flowing in the same direction, with current flowing in different directions or alternate between the same and different directions depending on one or more sensed operating parameters. In some examples, additional switches are used to switch the direction of the current.

For example in FIG. 3F, the array of inductive coils 216 includes two or more coils 350 including inductive coils 352 and 354 that are inter-wound. In other words, the turns of the inductive coils 352, 354 are wound between each other. The inductive coils 352, 354 can be driven by the same RF direct drive circuit or different RF direct drive circuits. In some examples, the outer inductive coil 352 and the inner inductive coil 354 are driven with current flowing in the same direction, with current flowing in different directions, or alternate between the same and different directions depending on one or more sensed operating parameters.

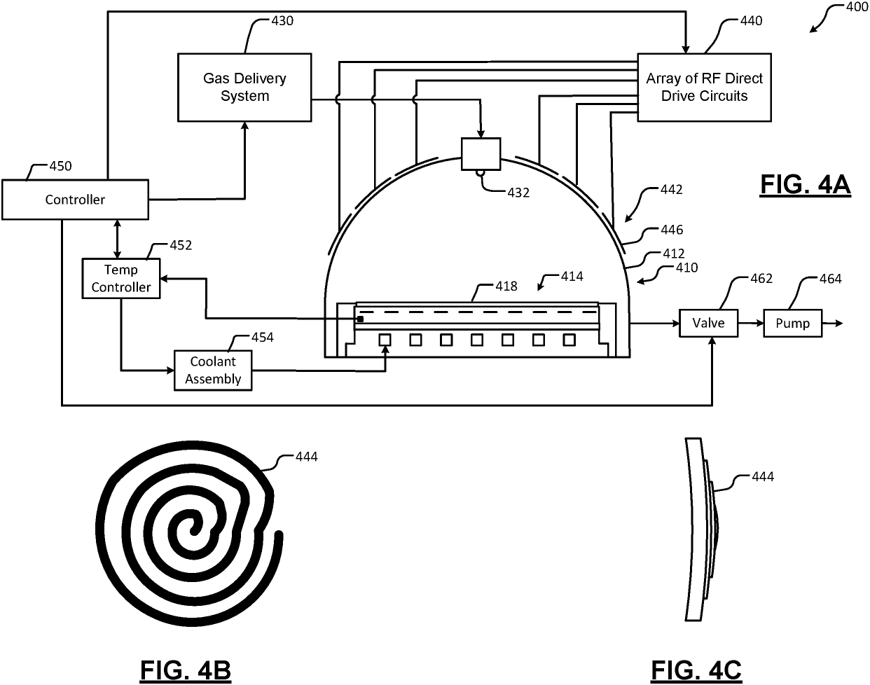

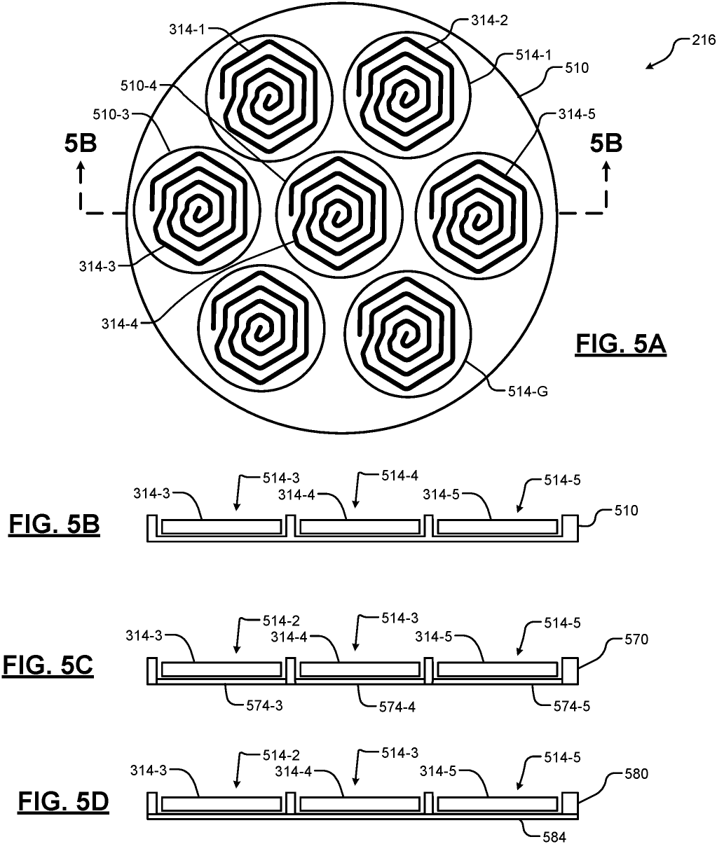

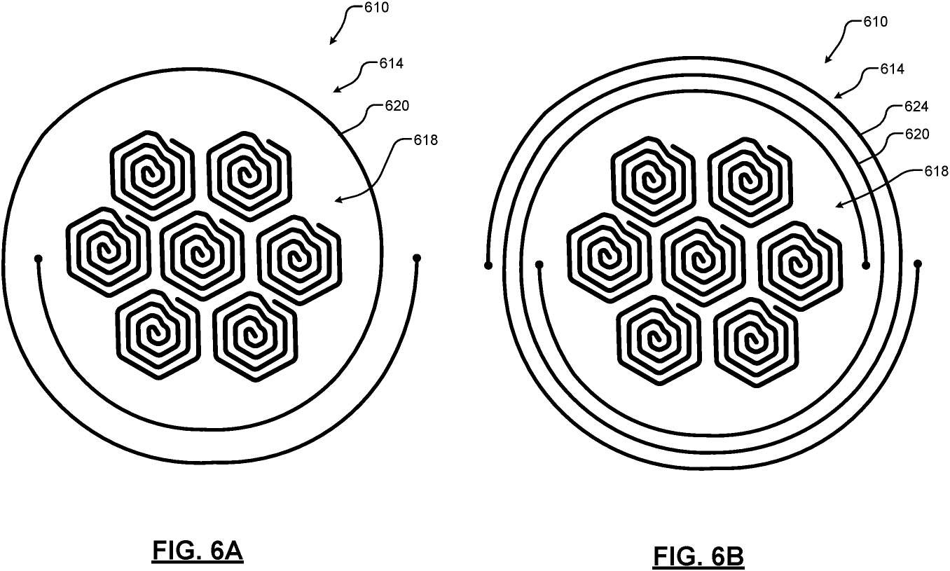

Referring now to FIGS. 4A to 4C, another substrate processing system 400 includes a processing chamber 410. In the preceding examples, the processing chamber has a rectangular side cross-section and the array of coils is generally arranged along a top surface of the processing chamber in a plane parallel to the substrate during processing. However, the processing chamber 410 in FIG. 4A includes a non-planar outer surface 412. In some examples, the chamber is made of a material that is substantially transparent (e.g. low attenuation) to the magnetic fields generated by the inductive coils at the operating frequency. In some examples, the non-planar outer surface of the processing chamber 410 is dome-shaped, although other types of surfaces such as cylinders, cones or other non-planar surfaces may be used.

A substrate support 414 is arranged in the processing chamber 410 to support a substrate 418 during processing. A gas delivery system 430 delivers process gas, etch gas, carrier gas, inert gas, precursor gas and/or other gases to the processing chamber 410. In some examples, the gas delivery system 430 outputs the gas mixture to the processing chamber 410 using a gas injector 432.

An array of RF direct drive circuits 440 output RF power to an array of inductive coils 442 arranged around an outer surface of the non-planar outer surface 412. A controller 450 may be used to control the process. The controller 450 communicates with the gas delivery system 430 to determine gas selection, timing and gas flows. The controller 450 communicates with the array of RF direct drive circuits 440 to control RF power, timing and switching of switches. The controller 450 communicates with a temperature controller 452, a temperature sensor 453 and a coolant assembly 464 to control a temperature of the substrate. The controller 450 communicates with a valve 462 and pump 454 to control chamber pressure or vacuum and/or to control evacuation of reactants from the processing chamber 410.

In FIGS. 4B and 4C, inductive coils 444 in the array of inductive coils 442 may have a shape that conforms to the non-planar outer surface 412 of the processing chamber 410. For example, the inductive coils 444 may have an arcuate side cross-section in one or two directions as shown in FIG. 4C to allow the coils to follow the surface of the processing chamber 410, to provide uniform spacing and/or to reduce plasma non-uniformity.

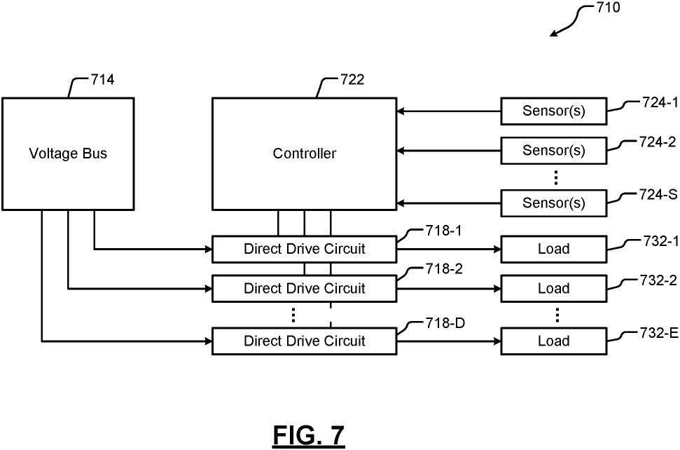

Referring now to FIGS. 5A to 5D, since each of the inductive coils generates roughly 1/G of the overall power and the magnetic field strength is attenuated by the window, the magnetic field in the processing chamber can be increased by reducing the thickness of the dielectric window between the inductive coils of the array and the processing chamber. In FIG. 5A, the inductive coils 314-1, 314-2, ..., and 314-G of the array of inductive coils 216 can be located in cavities 514-1, 514-2, ..., and 514-G, respectively, (collectively cavities 514) formed in a dielectric window 510. In FIG. 5B, the dielectric window 510 has a thickness T in areas that don’t include the cavities and a thickness t in areas including the cavities, where t < T.

In FIG. 5C, the dielectric window 510 includes a frame portion 570 and dielectric windows 574-1, 574-2, ..., and 574-G (only 574-3, 574-4 and 574-5 are shown) (collectively dielectric windows 574). In this example, the frame portion 570 can be made of dielectric material or another suitable material. In some examples, the coefficient of thermal expansion (CTE) of the materials used in the frame portion 570 and the dielectric windows 574 are the same or are within 5%, 4%, 3%, 2% or 1% of one another.

In FIG. 5D, the dielectric window 510 includes a frame portion 580 and a dielectric window 584 attached to a bottom surface of the frame portion 580. In this example, the frame portion 580 can be made of dielectric material or another suitable material. In some examples, the frame portion 580 may be made of aluminum, anodized aluminum, and/or a dielectric material having a lower grade or purity as compared to the dielectric window 584. In some examples, the coefficient of thermal expansion (CTE) of the materials used in the frame portion 580 and the dielectric window 584 are the same or are within 5%, 4%, 3%, 2% or 1% of one another. Referring now to FIGS. 6A and 6B, one or more additional inductive coils 614 are arranged around an array of coils 618. In FIG. 6A, the one or more inductive coils 614 include a single circular-shaped coil 620 that surrounds the array of coils 618. In FIG. 6B, the one or more inductive coils 614 includes a two circular-shaped coils 620, 624 that are inter-wound and that surrounds the array of coils 618. Referring now to FIG. 7, a drive circuit 710 for driving loads such as RF coils or RF electrodes is shown. A voltage source 714 provides voltage to an array of direct drive circuits 718-1, 718-2, ..., and 718-D, (collectively direct drive circuits 718) where D is an integer greater than two. Alternately, each of the RF direct drive circuits may include a separate voltage source and/or two or more the RF direct drive circuits may share a single voltage source. The array of direct drive circuits 718-1, 718-2, ..., and 718-D drive loads 732-1, 732-2, ..., and 732-E, respectively, (where E is an integer greater than two). While a 1:1 correspondence is shown between D and E, D can be greater than or equal to or less than or equal to E. In other words, outputs of multiple RF direct drive circuits can be connected in parallel to drive a single electrode or a group of electrodes such as those arranged in the same zone.

A controller 722 generates drive signals for control terminals or gates of switches in the direct drive circuits 718. In some examples, one or more sensors 724-1, 724-2, ..., and 724-S, where S is an integer greater than zero (collectively sensors 724), sense an operating parameter. In some examples, S is equal to D and/or S is equal to E. In other examples, S is not equal to D and/or S is not equal to E. The sensors 724 sense operational parameters such as voltage, current, phase offset or other measurable or estimated operating parameter indicative of plasma conditions specific to a particular one of the RF direct drive circuits and/or indicative of plasma conditions in general.

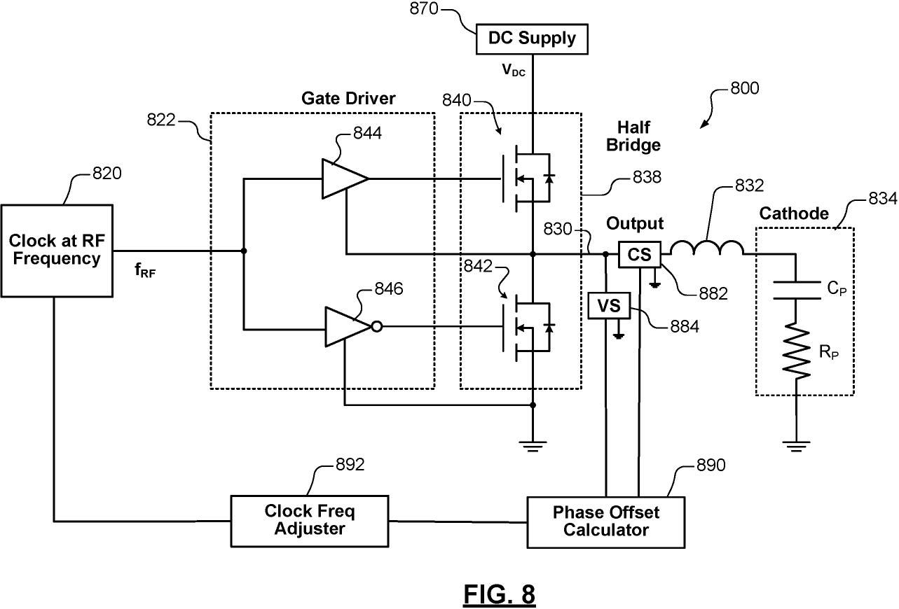

Referring now to FIG. 8, an example of an RF direct drive circuit 800 for supplying RF plasma power is shown. The RF direct drive circuit 800 includes a clock 820 that operates at one or more selected RF frequencies. The clock signal output by the clock 820 is input to a gate driver circuit 822. In some examples, the gate driver circuit 822 includes an amplifier 844 and an inverting amplifier 846 having respective inputs connected to the clock 820.

Outputs of the gate driver circuit 822 are input to a bridge circuit 838. In some examples, the bridge circuit 838 is a half-bridge circuit, although a full bridge circuit can be used. In some examples, the bridge circuit is balanced, although an unbalanced bridge circuit can be used. In some examples, the bridge circuit 838 includes a first switch 840 and a second switch 842. In some examples, the first switch 840 and the second switch 842 include metal oxide semiconductor field effect transistors (MOSFETs). The first switch 840 and the second switch 842 each include a control terminal, and first and second terminals. An output of the amplifier 844 of the gate driver circuit 822 is input to the control terminal of the first switch 840. An output of the inverting amplifier 846 of the gate driver circuit 822 is input to the control terminal of the second switch 842.

An output node 830 is connected to the second terminal of the first switch 840 and to the first terminal of the second switch 842. The first terminal of the first switch 840 is connected to a first DC supply 870. The second terminal of the second switch 842 is connected to a reference potential such as ground.

The output node 830 is connected by an inductor 832 to a cathode 834. In some examples, a capacitance Cₚ in series with a resistance Rₚ may be used to model the impedance seen by the RF direct drive circuit 800 (e.g. plasma capacitance and resistance, the capacitance and resistance of the electrode (or another component) in the substrate support and/or other stray or parasitic capacitance and resistance).

In some examples, instead of using the first DC supply 870 and ground, the RF direct drive circuit can include first and second DC supplies operating at +V_{DC}/2 and -V_{DC}/2, respectively. To achieve the same output RF power, both the first and second DC supplies operate at half the voltage of the single DC supply shown in FIG. 8. In some examples, the first DC supply and the second DC supply operate at approximately the same magnitude and opposite polarity. As used herein, approximately the same refers to a difference between a magnitude of the DC voltage output by the first DC supply 870 relative to the second DC supply 880 that is less than 20%, 5% or 2%. The first DC supply is connected to the first terminal of the first switch 840. The second DC supply is connected to the second terminal of the second switch 842.

In some examples, a current sensor 882 and a voltage sensor 884 sense current and voltage at the output node 830. A phase offset calculator 890 receives sensed current and voltage signals and generates a phase offset signal that is output to a clock frequency adjuster 892. The clock frequency adjuster 892 generates a clock adjustment signal based on the phase offset signal. In other features, the clock frequency adjuster 892 increases the frequency of the clock 820 when the current leads the voltage and decreases the frequency of the clock 820 when the voltage leads the current. Additional details relating to the direct drive circuit described in FIG. 8 can be found in commonly-assigned U.S. Pat. No. 10,515,781, entitled “Direct Drive RF Circuit for Substrate Processing Systems”, issued on Dec. 24, 2019, which is hereby incorporated by reference in its entirety.

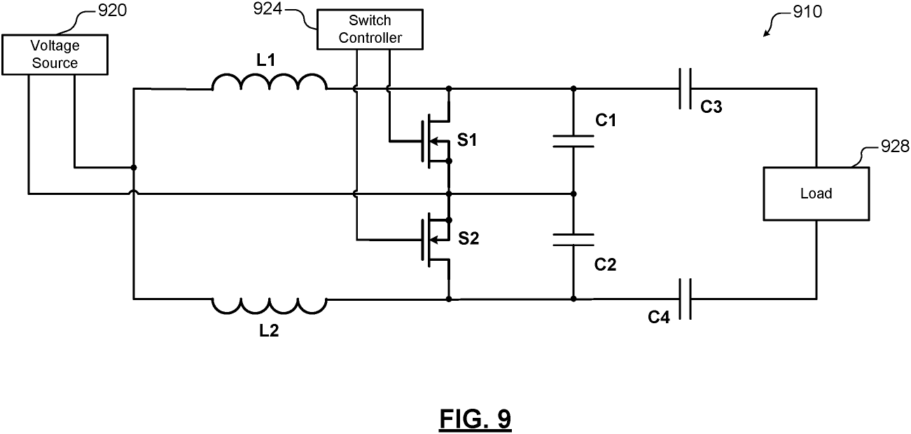

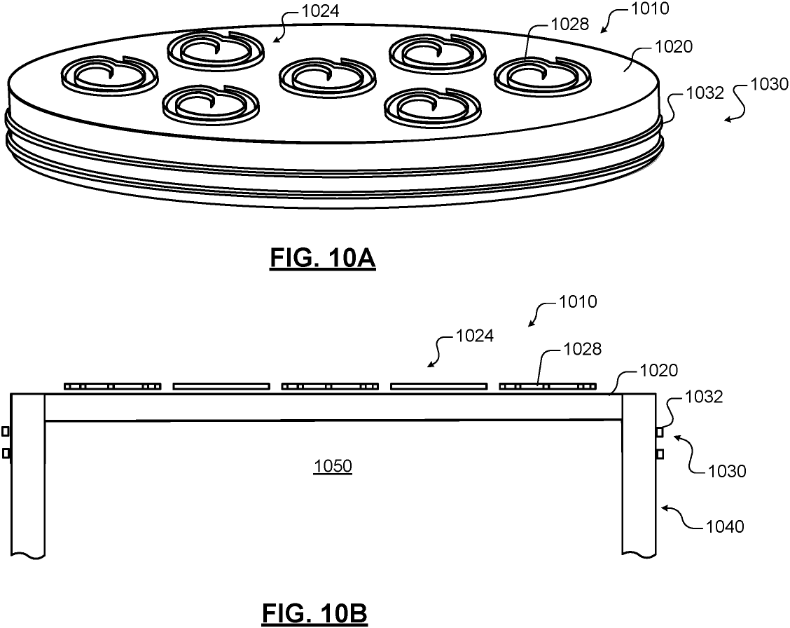

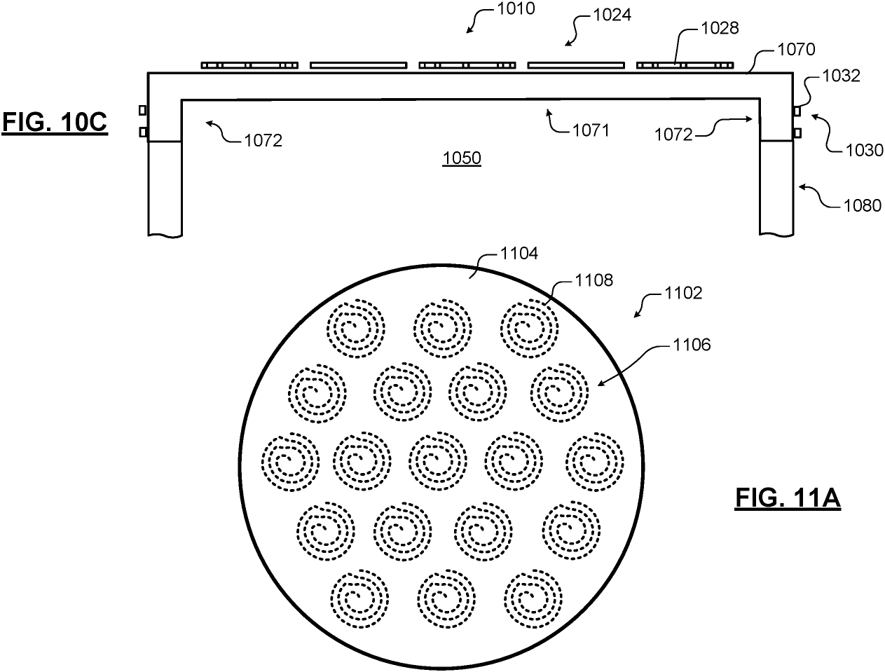

Referring now to FIG. 9, another example of an RF direct drive circuit 910 is shown. The RF direct drive circuit 910 includes a voltage source 920 that supplies voltage. In some examples, the voltage source 920 provides DC voltage, although other types of voltage sources can be used. In some examples, two or more RF direct drive circuits 910 can be supplied by the voltage source 920. Alternately, each of the RF direct drive circuits or sub-groups of the RF direct drive circuits can be connected to a voltage bus.

Inductor L1 has one terminal connected to a first terminal the voltage source 920 and another terminal connected to a first terminal of a switch S1 and first terminals of capacitors C1 and C3. Inductor L2 has one terminal connected to the first terminal of the voltage source 920 and another terminal connected to a second terminal of a switch S2 and first terminals of capacitors C2 and C4. A second terminal of the switch S1 is connected to a first terminal of the second switch S2, a second terminal of the voltage source 920 and a node between capacitors C1 and C2.

The controller 722 in FIG. 7 outputs drive signals to control terminals of the switches S1 and S2 in each of the RF direct drive circuits. Second terminals of the capacitors C3 and C4 are connected to a load 928. The load 928 can include an RF electrode or an inductive coil or an array as described herein.

In some examples, the switches S1 and S2 are implemented as semiconductor devices operating as switches. Each of the switches may be implemented by two or more switches connected in parallel. In some examples, the switches S1 and S2 are implemented as high electron mobility transistors, metal oxide semiconductor field effect transistors (MOSFETs), bipolar junction transistors (BJTs), silicon carbide (SiC) or gallium nitride (GaN) FETs, insulated gate BJTs (IGBJTs), diodes, silicon controlled rectifiers and/or combinations thereof.

In some examples, the switches S1 and S2 are driven 180 degrees out of phase at a desired frequency of operation. In other words, the duty cycle of the switches is generally about 50%. However, the controller 722 may receive feedback from one of the sensors 724 associated with one or more of the RF direct drive circuits. The controller 722 may alter the duty cycle and/or frequency based on the feedback to adjust operation of one or more of the RF direct drive circuits and alter plasma characteristics associated with the corresponding RF direct drive circuit.

Additional details relating to the direct drive circuit described in FIG. 9 can be found in U.S. Pat. Publication No. US 2019/0007004, published on Jan. 3, 2019, which is hereby incorporated by reference. In some examples, the inductors L1 and L2 can be implemented in air core inductors or using a PCB with metal traces.

Referring now to FIGS. 10A to 10C, additional coils systems that include an array of coils and one or more other coils are shown. In FIG. 10A, a substrate processing system includes a coil system 1010 that includes an array of coils 1024 that are arranged adjacent to a dielectric window 1020 in a first plane on an atmospheric side. The coil system 1010 further includes one or more coils 1030 that are wound (one or more times) around an upper portion of side walls 1040 of the processing chamber 1050 on an atmospheric side below the first plane as shown. While a single coil 1032 is shown with two turns, additional coils and/or additional or fewer turns per coil can be used. In this example, the upper portions of the side walls 1040 are made of dielectric material to allow the magnetic field generated by the one or more coils 1030 to pass through.

In FIG. 10B, the array of coils 1024 is driven using an array of RF direct drive circuits as described herein. The one or more coils 1030 can be driven by an RF source and matching network or by one or more RF direct drive circuits. In the example in FIG. 10C, a window 1070 has a “C”-shaped cross-section with a center portion 1071 and side portions 1072 extending therefrom. The center portion 1071 is cylindrical and the side portions 1072 extend downwardly from a radially outer edge of the center portion 1071 in a direction towards side walls 1080 of the processing chamber 1050.

As will be described further below, a larger number of smaller coils can be used for improved plasma uniformity and/or flexibility of adjustment. For example, 19 smaller coils on the order of 1″ to 3″ in diameter can be used with a thinner dielectric window on the vacuum side. In some examples, the coils are embedded in the dielectric window having a thickness from 1/16″ to ¾″ (e.g. ¼″) from the vacuum side. The thinner dielectric window can be bonded to a thicker dielectric window with the coils sandwiched in between. The combined thickness of the dielectric window is selected to withstand atmospheric pressure and/or implosion risk. In some examples, the coils are energized by wires passing through the dielectric window on the atmospheric side.

In other examples, the smaller coils are indirectly powered by another set of coils located on the atmospheric side of the dielectric window. For example, the coils on the atmospheric side can be larger (e.g. 3″ to 7″). Power is coupled wirelessly from atmospheric coils to the embedded coils to deliver RF power that ignites and supports the plasma.

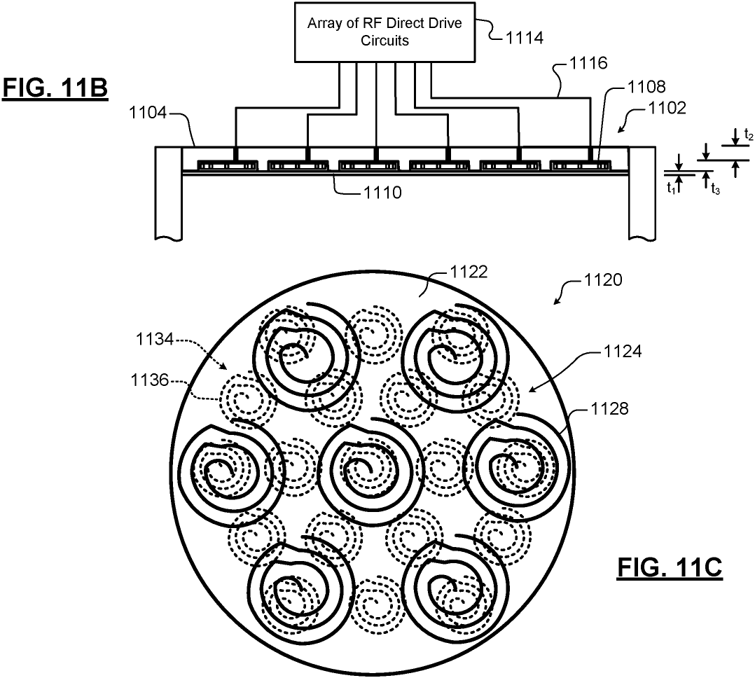

Referring now to FIGS. 11A and 11B, additional coils systems that include an array of coils is shown. In FIG. 11A, a coil system 1102 includes a first array 1106 including P coils 1108 that are embedded in a dielectric window assembly including a dielectric window 1104. In FIG. 11B, the dielectric window 1104 includes a bottom surface defining a plurality of cavities. Another dielectric window 1110 is arranged adjacent to the first array 1106 on the vacuum side. In other examples, the cavities may be defined on the dielectric window 1110 or the dielectric windows 1104 and 1110 can have rectangular cross-sections and spacers can be used between the P coils 1108 of the first array 1106 instead of defining cavities in either of the dielectric windows to reduce cost. An array of RF direct drive circuits 1114 is directly connected by conductors 1116 passing through the dielectric window 1104 to the P coils 1108 of the first array 1106. The dielectric window 1110 has a thickness t₁, the dielectric window 1104 has a thickness t₂ and the coils have a thickness t₃. In some examples, t₁ is less than t₂.

Referring now to FIGS. 11C and 11D, the embedded array of coils can be powered remotely without a direct connection. In FIG. 11C, an upper portion of a substrate processing system is shown. The substrate processing system includes a coil system 1120 with a first array 1124 including a plurality of coils 1128 arranged adjacent to a dielectric window assembly 1122 on the atmospheric side outside of the processing chamber. The dielectric window assembly 1122 can be similar to FIG. 11B without holes for conductors 1116. The coil system 1120 further includes a second array 1134 including a plurality of coils 1136 that are embedded within the dielectric window assembly 1122.

In FIG. 11D, the plurality of coils 1128 of the first array 1124 are generally located in a first plane parallel to and above a second plane including a top surface of the dielectric window assembly 1122. The plurality of coils 1136 in the second array 1134 are located in a third plane below the second plane. When powered by RF direct drive circuits (or RF source and matching network), the plurality of coils 1128 of the first array 1124 generate magnetic fields that couple with and deliver RF energy to the plurality of coils 1136 in the second array 1134. The plurality of coils 1136 in the second array 1134, in turn, deliver RF energy to process gases inside of the chamber to ignite and maintain plasma.

In some examples, the plurality of coils 1128 has an outer dimension that is larger than the plurality of coils 1136 that are embedded in the dielectric window assembly 1122. In some examples, the first array 1124 includes fewer coils than the second array 1134. For example only, the first array 1124 includes 7 coils with an outer dimension of 4′ to 7″ (e.g. 6″) and the second array 1134 includes 19 coils having an outer dimension of 1″ to 3″ (e.g. 2″), although other diameters, shapes and numbers of coils can be used. Note that in FIG. 11B, two of the plurality coils 1128 that would normally appear behind the coils 1128 were omitted from the cross-section for clarity. In still other examples, an additional set of coils can be wound around an upper portion of the processing chamber as shown in FIGS. 10A to 10C to deliver RF energy to the second array 1134.

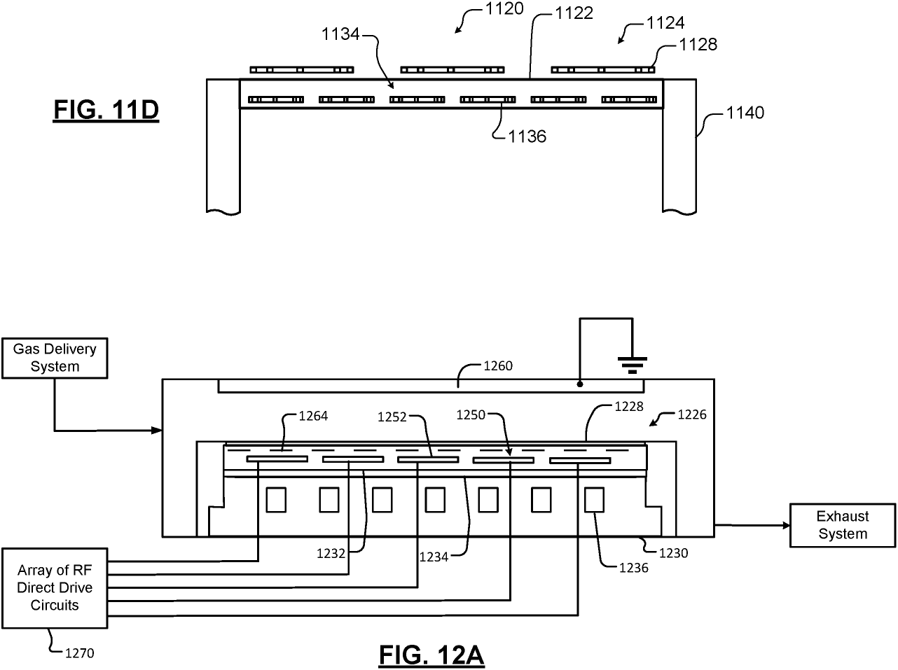

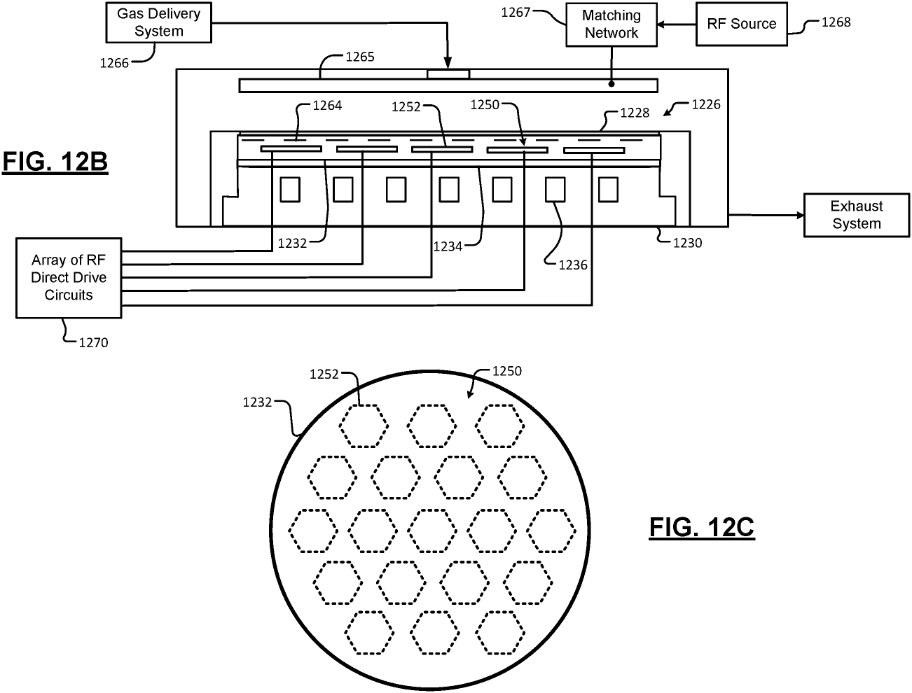

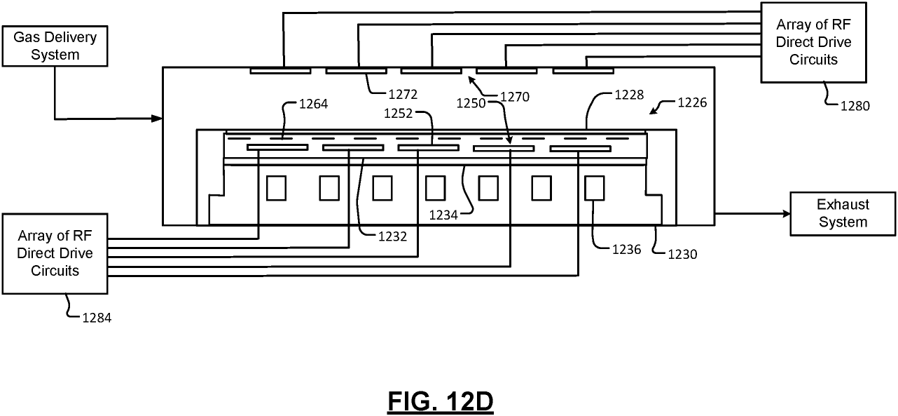

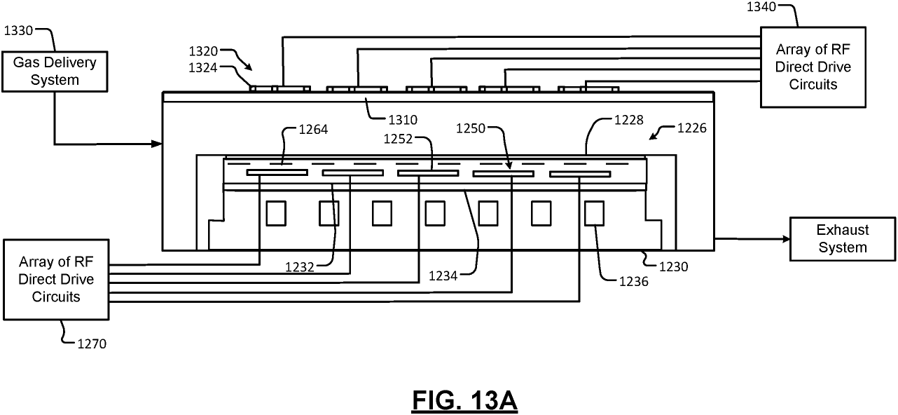

Referring now to FIG. 12A, a substrate support includes a baseplate 1230 that that supports a layer 1232, which may correspond to a ceramic multi-zone heating layer. A bonding layer 1234 may be arranged between the layer 1232 and the baseplate 1230. The baseplate 1230 may include one or more channels 1236 for flowing coolant through the baseplate 1230.

An array 1250 of electrodes 1252 can be arranged in the layer 1232. The array 1250 of electrodes 1252 are driven by an array of RF direct drive circuits 1270 to provide an RF bias to the substrate. An upper electrode 1260 that is arranged above the substrate support 1226 can be either unpowered or powered. If unpowered, the upper electrode 1260 may be connected to a reference potential such as ground (as shown). The array of RF direct drive circuits 1270 supply RF power to the array 1250 of electrodes 1252 as described herein to provide the RF bias to the substrate. Heaters and/or electrostatic electrodes generally identified at 1264 can be arranged in the layer 1232 above or below the array 1250 of electrodes 1252.

Referring now to FIG. 12B, the upper electrode can also be powered. A substrate processing system includes a showerhead 1265 (with an internal plenum and gas though holes (not shown)) supplied by a gas delivery system 1266. The showerhead 1265 can be made of conducting material (or non-conducting material with an embedded conducting electrode). RF power is supplied to the showerhead 1265 by an RF source 1268 and a matching network 1267 (or by one or more RF direct drive circuits). In FIG. 12C, the layer 1232 of the substrate support 1226 is shown with the array of array 1250 of electrodes 1252 embedded therein.

Referring now to FIG. 12D, the upper electrode may include a second array 1270 of electrodes 1272 that are driven by an array of direct drive circuits 1280. The array 1250 of electrodes 1252 are driven by RF direct drive circuits 1284 to provide an RF bias to the substrate.

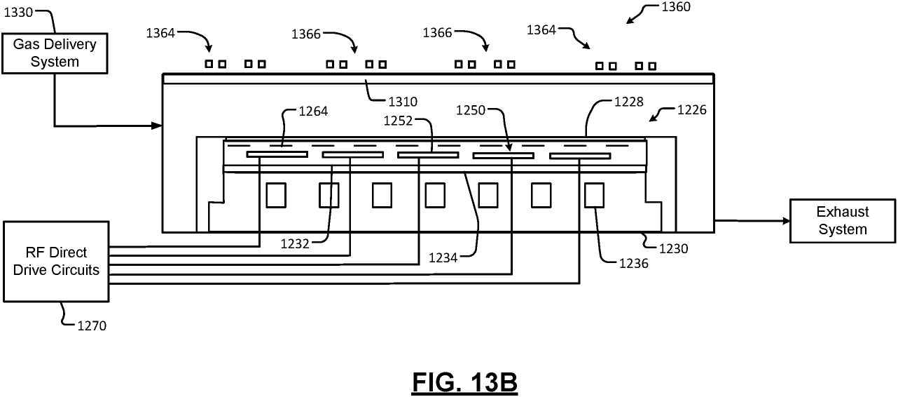

Referring now to FIG. 13A, a substrate processing system includes arrays of coils arranged adjacent to the dielectric window and array of electrodes that are embedded in the substrate support and that are driven by RF direct drive circuits. The substrate processing system includes an array 1320 including a plurality of coils 1324 that are arranged adjacent to a dielectric window 1310 of a processing chamber. The plurality of coils 1324 of the array 1250 are driven by RF direct drive circuits 1340 as described herein to deliver RF energy to ignite process gases in the substrate processing chamber. The array 1250 of electrodes 1252 described above generates the RF substrate bias during processing.

Referring now to FIG. 13B, a substrate processing system includes coils 1360 that are arranged adjacent to the dielectric window 1310. The coils 1360 can be driven by one or more RF sources and matching networks and/or one or more RF direct drive circuits. The substrate processing system further includes the array 1250 with a plurality of electrodes 1252 that are embedded in the substrate support and that are driven by the array of RF direct drive circuits 1270. The coils 1360 may include one or more coils each with one or more turns. In the example in FIG. 13B, the coils 1360 include outer coils 1364 and inner coils 1366 that are arranged within the outer coils 1364. In some examples, the outer coils 1364 and/or the inner coils 1366 include two or more inter-wound coils as described above.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system, comprising:
a processing chamber including a window;
a substrate support arranged inside the processing chamber to support a substrate during plasma processing;
a first array including E inductive coils arranged adjacent to and outside of the processing chamber, where E is an integer greater than three; and
a second array including D RF direct drive circuits configured to output RF power to the first array, where D is an integer greater than three, and to generate plasma inside of the processing chamber.

2. The substrate processing system of claim 1, wherein a distance between a top surface of the substrate support and a bottom surface of the window is in a range from 0.4″ to 6″.

3. The substrate processing system of claim 1, wherein a distance between a top surface of the substrate support and a bottom surface of the window is in a range from 1″ to 3″.

4. The substrate processing system of claim 1, wherein the E inductive coils have one of a circular outer shape and a hexagonal outer shape.

5. The substrate processing system of claim 1, wherein the E inductive coils are arranged in one of a rectangular array and a hexagonal array.

6. The substrate processing system of claim 1, wherein the E inductive coils have an outer diameter in a range from 1″ to 6″.

7. The substrate processing system of claim 1, wherein the E inductive coils have an outer diameter in a range from 3″ to 6″.

8. The substrate processing system of claim 1, wherein the first array further includes F inductive coils have at least one of a size and a shape that is different than the E inductive coils, where F is an integer greater than two.

9. The substrate processing system of claim 1, wherein each of the E inductive coils includes a first inductive coil arranged inside of a second inductive coil.

10. The substrate processing system of claim 1, wherein each of the E inductive coils includes a first inductive coil inter-wound with a second inductive coil.

11. The substrate processing system of claim 1, wherein the window is made of a dielectric material.

12. The substrate processing system of claim 1, wherein the window includes a frame portion and defines E cavities, wherein the E inductive coils in the first array are arranged in the E cavities of the frame portion.

13. The substrate processing system of claim 12, further comprising E windows arranged in a substrate-facing opening of the E cavities.

14. The substrate processing system of claim 12, further comprising a dielectric window arranged on a substrate-facing side of the frame portion.

15. The substrate processing system of claim 1, wherein each of the D RF direct drive circuits includes:
a clock generator to generate a clock signal at a first frequency;
a gate driver to receive the clock signal;
a bridge circuit including:
a first switch with a control terminal connected to the gate driver, a first terminal and a second terminal;
a second switch with a control terminal connected to the gate driver, a first terminal connected to the second terminal of the first switch and an output node, and a second terminal;
a first DC supply to supply a first voltage potential to the first terminal of the first switch; and
a second DC supply to supply a second voltage potential to the second terminal of the second switch.

16. The substrate processing system of claim 15, wherein the first voltage potential and the second voltage potential have opposite polarity and are approximately equal in magnitude.

17. The substrate processing system of claim 15, wherein the second voltage potential is ground.

18. The substrate processing system of claim 15, further comprising:
a current sensor to sense current at the output node and to generate a current signal;
a voltage sensor to sense a voltage at the output node and to generate a voltage signal; and
a controller including:
a phase offset calculator to calculate a phase offset between the voltage signal and the current signal; and
a clock adjuster to adjust the first frequency based on the phase offset.

19. The substrate processing system of claim 18, wherein the clock adjuster increases the first frequency when the current leads the voltage and decreases the first frequency when the voltage leads the current.

20. The substrate processing system of claim 1, wherein each of the D RF direct drive circuits includes:
a first inductor including a first end and a second end;
a second inductor including a first end in communications with the first end of the first inductor and a second end;
a first switch including a first terminal, a second terminal and a control terminal;
a second switch including a first terminal, a second terminal and a control terminal;
a first capacitor including a first end and a second end, wherein the first end of the first capacitor is in communication with the second end of the first inductor and the first terminal of the first switch; and
a second capacitor including a first end and a second end, wherein the second end of the second capacitor is in communication with the second end of the second inductor and the second terminal of the second switch,
wherein the second terminal of the first switch communicates with the first terminal of the second switch, the second end of the first capacitor and the first end of the second capacitor.

21. The substrate processing system of claim 20, further comprising:
a third capacitor including a first end in communication with the first end of the first capacitor and a second end in communication with a first end of at least one of the E inductive coils; and
a fourth capacitor including a first end in communication with the second end of the second capacitor and a second end in communication with a second end of the at least one of the E inductive coils.

22. The substrate processing system of claim 20, further comprising a voltage source having one end connected to the first end of the first inductor and the first end of the second inductor and a second end connected to the second terminal of the first switch and the first terminal of the second switch.

23. The substrate processing system of claim 1, further comprising an inductive coil surrounding the first array.

24. The substrate processing system of claim 1, further comprising:
a controller configured to control the second array; and
S sensors configured to sense S operational parameters corresponding to the second array, respectively, where S is an integer greater than three,
wherein the controller is configured to alter operation of the D RF direct drive circuits based on the S operational parameters sensed by the S sensors, respectively.

25. The substrate processing system of claim 1, wherein:
the processing chamber includes side walls and further comprising one or more inductive coils each including one or more turns wound around an upper portion of the side walls, and
wherein the first array is arranged in a first plane above the window and the one or more inductive coils are arranged below the first plane.

26. The substrate processing system of claim 1, further comprising a third array including F inductive coils that are embedded within the window, where F is an integer greater than three, wherein the E inductive coils deliver RF energy to the F inductive coils.

27. The substrate processing system of claim 26, wherein the E inductive coils of the first array are larger than the F inductive coils of the third array.

28. The substrate processing system of claim 27, wherein F is greater than E.

29. The substrate processing system of claim 27, further comprising:
a third array including G electrodes embedded in the substrate support, where G is an integer greater than three; and
a fourth array including H RF direct drive circuits configured to output RF power to the first array, where H is an integer greater than three.

30. The substrate processing system of claim 1, further comprising:
a third array including G electrodes embedded in the substrate support, where G is an integer greater than three; and
a fourth array including H RF direct drive circuits configured to output RF power to the first array, where H is an integer greater than three.
